(19) United States
(12) Patent Application Publication
(10) Pub. No.: US 2008/0184935 A1
(43) Pub. Date: Aug. 7, 2008

(54) CLAMPING DEVICE FOR HOLDING A SUBSTRATE

(75) Inventor: Thomas Klug, Grossostheim (DE)

Correspondence Address: PATTERSON & SHERIDAN, LLP - - APPM/TX, 3040 POST OAK BOULEVARD, SUITE 1500, HOUSTON, TX, 77056, US

(73) Assignee: APPLIED MATERIALS,INC., Santa Clara, CA (US)

(21) Appl. No.: 11/696,468

(22) Filed: Apr. 4, 2007

(30) Foreign Application Priority Data
Feb. 7, 2007 (DE) 20 2007 002 032.5

(51) Int. Cl. H01L 21/687

(52) U.S. Cl. 118/728

(57) ABSTRACT

The invention relates to a clamping device for holding a substrate. This clamping device includes a press-on fixture and a lower part, wherein at least the press-on fixture or the lower part includes at least a permanent magnet. If one of the two parts includes a permanent magnet, it suffices if the other part includes magnetizable material. A further permanent magnet can be provided, with which one end of the press-on fixture can be lifted up.

### FIELD OF THE INVENTION

The invention relates to a clamping device for substrates.

### BACKGROUND OF THE INVENTION

In sputter installations substrates are frequently moved adjacent a target, from the surface of which particles are sputtered off which are deposited on the substrate. As the substrates can be considered, for example, glass panes, which are transported through an inline sputter installation. These glass panes are embedded in frames connected with a transporting device, and this frame includes a holding apparatus, with which the glass pane can be fixed in this frame.

For example a device for the mounting of a mask of a ferromagnetic material on a planar substrate is known, in which the substrate is disposed between the mask and a frame (DE 29 707 686 U1). The frame includes at least one permanent magnet disposed in this frame.

A mounting disposition for the vertical mounting of a substrate is disclosed in DE 10 2004 027 898 A1. This mounting disposition serves for mounting the substrate in the suspended state and includes two clamping elements associated to each other, each element being provided with at least one contact face, between which the substrate is disposed in the mounting state. To secure the clamping elements, blocks are provided which are positioned with machine screws.

### SUMMARY OF THE INVENTION

The invention addresses the problem of providing a clamping device for substrates which is simple in structure and can be readily handled.

Embodiments of the invention consequently provide a clamping device for holding a substrate. This clamping device comprises a press-on fixture and a lower part, at least the press-on fixture or the lower part comprising at least one permanent magnet. If one of the two parts comprises a permanent magnet, it suffices if the other part comprises magnetizable material. Further, a permanent magnet can be provided with which one end of the press-on fixture can be raised.

This clamping device can simply be attached on a holding apparatus, for example a frame and, if necessary, can also be readily removed again. This has the advantage that a damaged clamping device can be replaced by a new one without great effort. The holding apparatus does not need to be completely disassembled for this purpose.

Since the clamping device is comprised of a low-cost material, the replacement of a damaged clamping device is cost-effective and readily managed due to the simple assembly.

### BRIEF DESCRIPTION OF THE DRAWINGS

Embodiment examples of the invention are shown in the drawing and will be explained in the following in further detail.

FIG. 1 is a perspective view of a clamping device with a substrate;

FIG. 2 is a side view of the clamping device with substrate depicted in FIG. 1;

FIG. 3 is the clamping device depicted in FIG. 2 after removal of the substrate;

FIG. 4 is a top view of the clamping device depicted in FIG. 1;,

FIG. 5 is a sectional view through the clamping device depicted in FIG. 1;

FIG. 6 is a variant of the clamping device with substrate depicted in FIG. 2;

FIG. 7 is the clamping device depicted in FIG. 6 after removal of the substrate;

FIG. 8 is a variant of the clamping device depicted in FIG. 1 to FIG. 5; and

FIG. 9 is a substrate disposed on a frame provided with clamping device.

### DETAILED DESCRIPTION

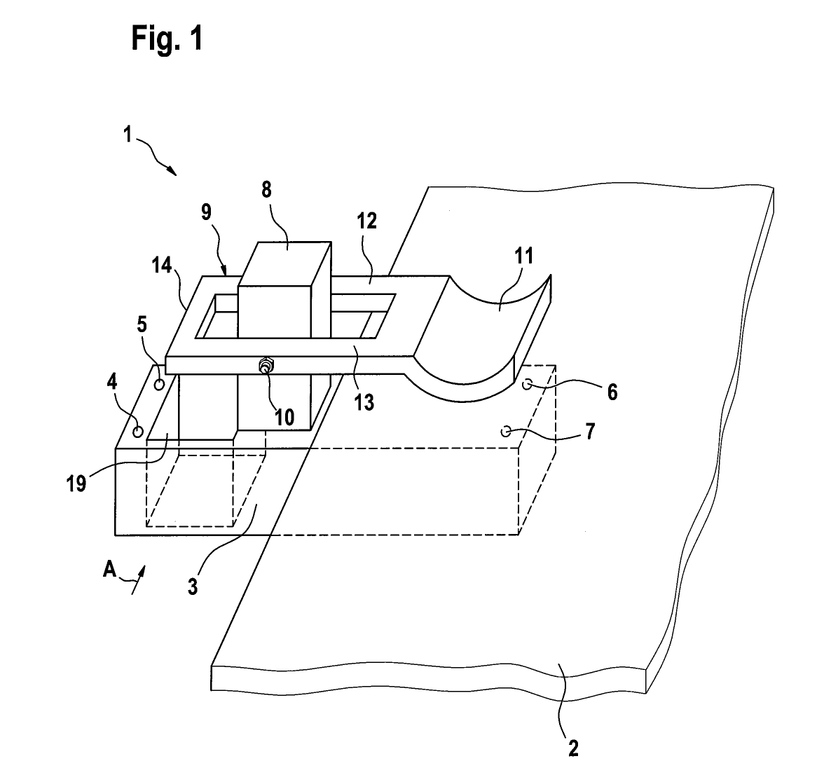

FIG. 1 depicts in perspective view a clamping device 1, by means of which a substrate 2 is held. The substrate may be, for example, a glass pane which is to be coated. Evident is a lower part 3 with several bores 4 to 7. These bores 4 to 7 serve the purpose of attaching the clamping device 1 on a frame by means of connecting elements. As the connecting elements may be used, for example, machine screws. However, frame as well as connecting elements are not shown in FIG. 1.

Adjoining the lower part 3 is a block 8, on which is disposed a press-on fixture 9 by means of a connecting bolt 10. The press-on fixture 9 includes a front portion 11 arched convexly in the direction of the lower part 3, which is adjoined by two parallel webs 12, 13, which, in turn, are connected to one another by a transverse web 14. The webs 12, 13 and the transverse web 14 together form a rectangular opening which encompasses the block 8. Instead of one block 8, two blocks may also be provided between which the press-on fixture 9 is located.

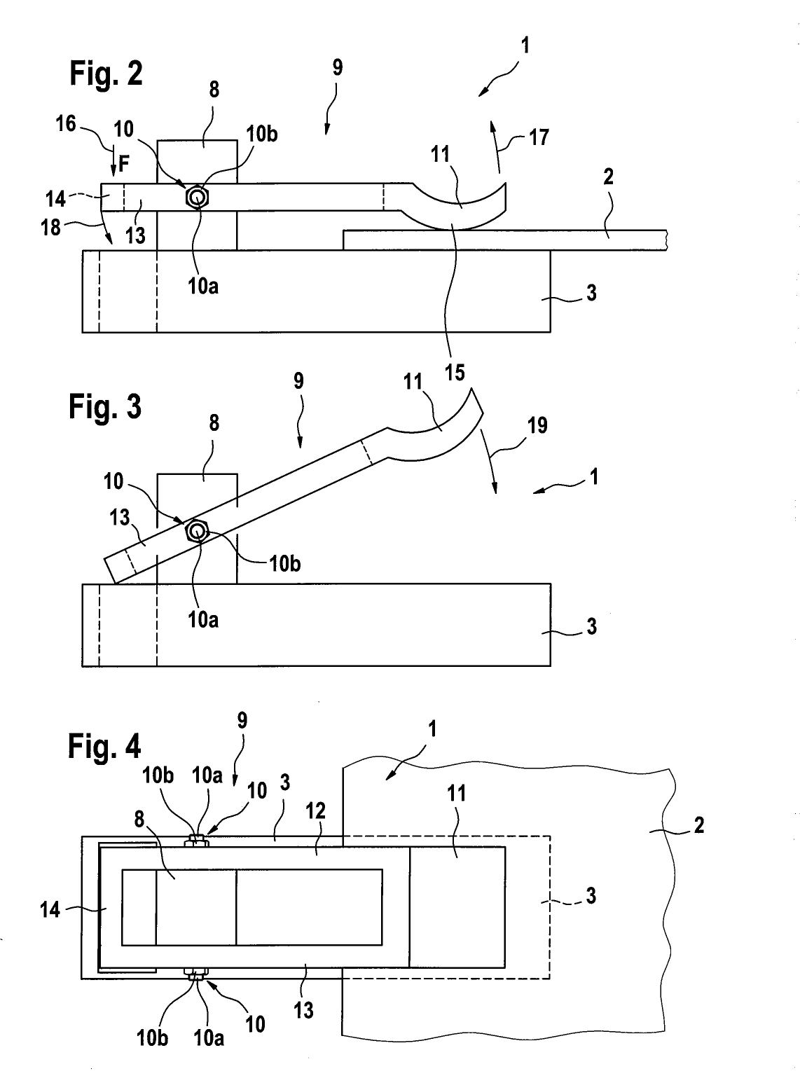

FIG. 2 depicts a side view of the clamping device 1 shown in FIG. 1, and specifically with view in the direction A. Evident is again the lower part 3 with the block 8 disposed thereon, on which the press-on fixture is located. This press-on fixture 9 is fastened on block 8 by means of the connecting bolt 10, which includes for example a machine screw 10a and a nut 10b.

It is also evident that the substrate 2, which to some extent rests in contact on the lower part 3, is also in contact with the lower portion 15 of the arched front portion 11. The substrate is consequently clamped in between a lower portion 15 of the arched front portion 11 and the lower part 3.

Since the press-on fixture 9 is only attached on the block 8 by a connecting bolt 10, the press-on fixture 9 can be moved through a force F acting onto the transverse web 14, which force acts in the direction of the lower part 3, i.e. preferably in the direction of arrow 16. Through this force F the arched front portion 11 is moved in the direction of arrow 17, i.e. away from lower part 3, and the transverse web 14 in the direction of arrow 16, i.e. toward the lower part 3. The substrate 2 is thereby no longer clamped between the lower part 3 and the lower portion 15 of arched front portion 11, whereby it can be removed out of the clamping device 1.

FIG. 3 shows the clamping device 1, depicted in FIG. 2, shortly after the removal of the substrate 2. The press-on fixture 9 assumes therein a position in which the arched front portion 11 is moved away from lower part 3 and the transverse web 14 toward the lower part 3. This permits a substrate to be placed onto the lower part 3. If force F is no longer engaging, the front portion 11 is again moved in the direction of the lower part, i.e. in the direction of arrow 19. It must be possible to open the press-on fixture 9 far enough for the substrate 2 to be removed in the forward direction, i.e. perpendicularly away from the carrier. For this purpose in the lower part 3 is provided a recess or cutout 19. It is also possible to provide a notch at the lower end of block 8. It is further possible to apply the connecting bolt 10 eccentrically on the block.

FIG. 4 shows a top view onto the clamping device 1 depicted in FIG. 1 with the substrate 2 clamped between the lower part 3 and the front portion 11 of the press-on fixture 9 and is thus held. Evident further is that the press-on fixture 9 is movably disposed on block 8 and is held by means of a connecting bolt 10. However, shown are only the nuts 10b and 10b′ of the connecting bolt 10.

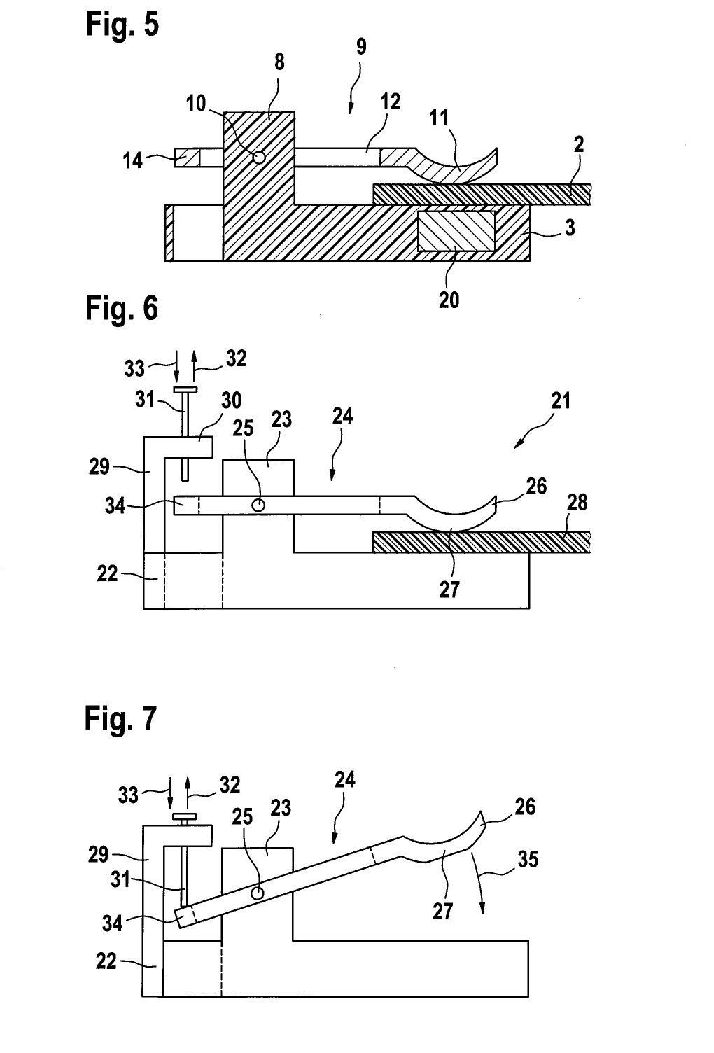

FIG. 5 shows a section through the clamping device 1 depicted in FIG. 1 in the viewing direction A. Consequently, the depiction of FIG. 5 corresponds to that of FIG. 2, with the difference that FIG. 5 is a sectional representation.

Seen can be the lower part 3 and block 8 through which penetrates the connecting bolt 10. Block 8 and lower part 3 are preferably comprised of the same material, for example Teflon® polymers (polytetrafluoroethylene), PEEK™ polymers (polyetheretherketone) or PVC polymers (polyvinylchloride). These two parts can thereby be produced simply and cost-effectively and the production may be carried out, for example, through injection molding processes.

In the region of lower part 3, above which is disposed the arched front portion 11 of the press-on fixture 9, is placed a magnet 20. Since the press-on fixture 9 is comprised of a magnetic or magnetizable material, for example sheet metal, a magnetic force acts onto the press-on fixture 9, which force presses the front portion 11 onto the substrate 2. The clamping mechanism therefore is based exclusively on magnetic force. It is understood that it is not necessary for the entire press-on fixture 9 to be comprised of magnetizable material. It suffices if only the front portion 11 is comprised of magnetizable material.

If the substrate 2 is to be removed from the clamping device 1, onto the transverse web 14 a force F must be exerted, which is stronger than the magnetic force. When this is the case, the front portion 11 is moved away from the lower part 3 and the substrate can be removed.

FIG. 6 shows a variant of the clamping device depicted in FIG. 2. This clamping device 21 also includes a lower part 22 with a block 23 seated thereon, on which a press-on fixture 24 is disposed. As in FIG. 2, the press-on fixture 24 is also fastened on the block 23 such that it is movable by means of a connecting element 25.

The press-on fixture 24 in FIG. 6 also comprises a front portion 26. However, this front portion 26 is not arched on the underside 27, but has a flattened underside 27, with which it rests on the substrate 28. Since the lower part 22 like the lower part 3 of clamping device 1 in FIG. 5 includes a magnet, the clamping force is also based on the magnetic force obtaining here. In contrast to the clamping device 1, this clamping device 21 includes an extension 29. This extension 29 is preferably comprised of the same material as the block 23 and the lower part 22.

The extension 29 has the shape of an upside-down “L”, which is obtained by rotation of this “L” by 180 degrees. Through the upper region 30 of the extension 29 is guided a pin 31, which can be moved in the direction of arrow 32 or 33, alternatively. This pin includes magnetic material or is entirely comprised of magnetic material. Since the clamping device 21 can be operated entirely without spring force, not only the clamping force between front portion 11 or 26, alternatively, and the permanent magnetic 20 is generated by means of magnetic attraction but the opened hollow arm 9 or 24, alternatively, is also moved through magnetic force from the position “open” into the clamping position. When pulling back pin 31, web 34 is entrained until the magnetic attraction between the permanent magnet 20 and the front position 11 or 26, alternatively, comes to bear again.

It is understood that extension 29 can also be implemented differently and even be disposed on block 23 itself. It is only important that it includes an element which fulfills the function of pin 31, namely that by means of this element the press-on fixture 24 can be moved away from the substrate 28 such that the substrate can be removed from the clamping device 21.

FIG. 7 shows the clamping device 21 depicted in FIG. 6 after the substrate 28 has been removed. To be able to remove the substrate 28, pin 31 was moved in the direction of arrow 33. Since the press-on fixture 24 also includes a transverse web 34, the front portion 26 of the press-on fixture 24 is moved through the force, with which pin 31 acts onto the transverse web 34, away from the lower part 22, such that substrate 28 can be removed from clamping device 21. The force, which is generated through the movement of pin 31 in the direction of arrow 33, must be greater than the magnetic force, in order for the front portion 26 of press-on fixture 24 to be moved in the direction of arrow 35 until the front portion 26 rests again with its underside 27 on the new substrate. The substrate is subsequently held through the magnetic force, which acts as clamping force.

Even though it is possible to move the pin 31 manually, it is of advantage if the movement of pin 31 is controlled for example by means of a computer. Since the clamping device 21 is only comprised of few parts, it has low susceptibility to wear. In order to avoid scratches on the substrate 28, on the lower part 27 of front portion 26 of press-on fixture 24 a synthetic material layer can additionally be disposed. However, such a synthetic material layer is not shown in FIG. 7.

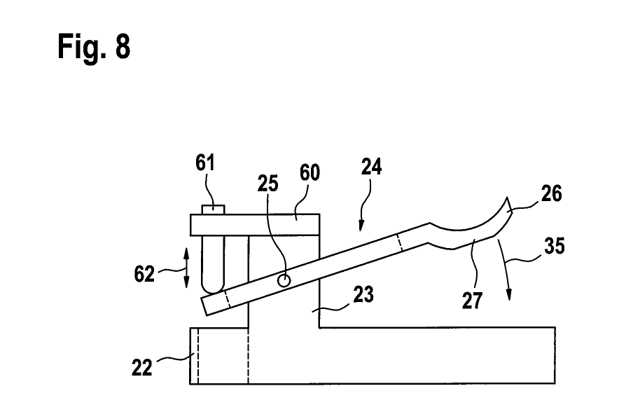

FIG. 8 depicts a variant of the clamping device, in which on the block 23 a transverse web 60 is disposed, through which a pusher 61 is movable in the direction of arrow 62. This pusher 61 is at least at its lower end magnetic. If only the rearward end of the press-on fixture 24 is magnetizable, with the pusher 61 the rearward end of press-on fixture 24 can be raised. Therewith an additional force between substrate 2 and press-on fixture 24 can be exerted. The mounting for the pusher 61 as well as the driving means with which it is moved, are not shown in FIG. 8. The pusher 61 is preferably disposed stationarily on the installation in a robot loading station or unloading station. Such a pusher 61 is electrically actuated through an installation control, such that the substrate can be removed from the installation by a robot or be placed onto a carrier, alternatively.

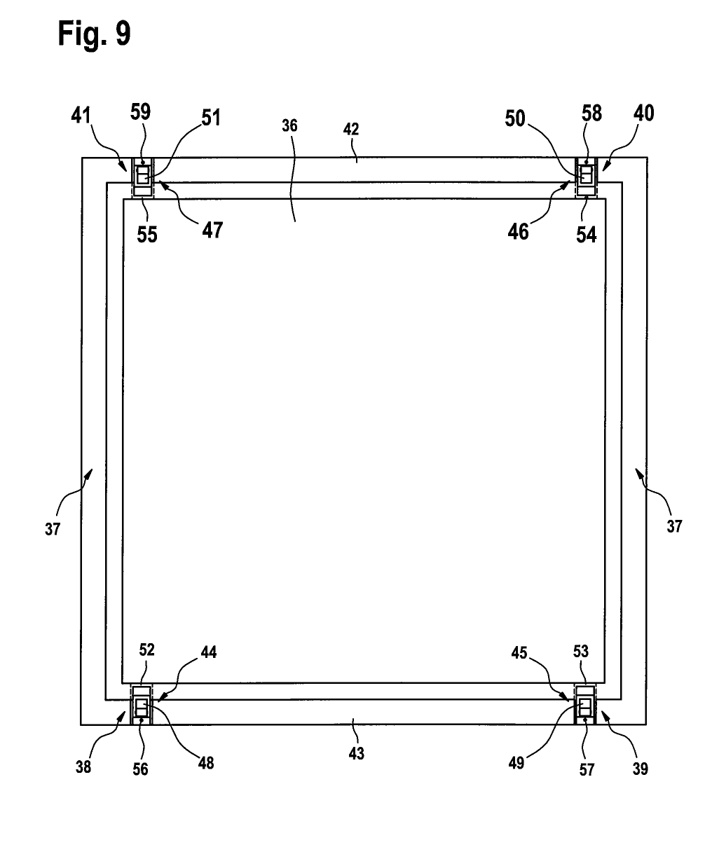

FIG. 9 shows a substrate 36 which is disposed on a frame 37. On this frame 37 are disposed four clamping devices 38 to 41, each of the clamping devices 38 to 41 being disposed on opposing frame sections 42 or 43, respectively. Consequently, in each instance two clamping devices 38, 41 and 40, 39 oppose one another.

These clamping devices 38 to 41, which hold the substrate 36, are structured analogously to the clamping device 21 depicted in FIG. 6 or FIG. 7.

As with the clamping device 21 depicted in FIG. 6 or 7, these clamping devices 38 to 41 also include press-on fixtures 44 to 47, which are each connected via connecting elements with a block 48 to 51. However, for the sake of clarity, the connecting elements are not shown in FIG. 8. Evident are further the front portions 52 to 55 of the press-on fixtures 44 to 47, which rest in contact on the margin region of substrate 36, whereby the substrate 36 is held in the clamping devices 38 to 41.

It can also be seen that each clamping device 38 to 41 includes a pin 56 to 59, through the actuation of which the front portions 52 to 55 of press-on fixtures 44 to 47 are raised. The substrate 36 can thereby be removed and replaced by a new substrate. Instead of a pin, a “pusher” can also be employed.

A substrate 36, such as is depicted in FIG. 9, can be held by the clamping force of the clamping devices alone, the number of clamping devices being adapted to the weight of the substrate 36. For very heavy substrates 36 a support ledge or support pins are provided at the lower web 43 of the carrier.

What is claimed is:

1. A clamping device for holding a substrate, comprising:
a lower part comprising a permanent magnet;
at least one block disposed on the lower part; and
a press-on fixture disposed on the at least one block, wherein the press-on fixture is pivoted swivellably in the block, and the press-on fixture is at least partially comprised of a magnetic or magnetizable material or includes a permanent magnet.

2. The clamping device as claimed in claim 1, wherein the press-on fixture comprises a front portion which includes magnetic or magnetizable material.

3. The clamping device as claimed in claim 2, wherein the front portion is connected with two webs which, together with a transverse web connecting them, form a cutout through which projects the block.

4. The clamping device as claimed in claim 3, wherein the two webs extend in parallel.

5. The clamping device as claimed in claim 1, wherein the press-on fixture is pivoted swivellably by means of an axle extending through the block, this axle resting with its ends in the webs.

6. The clamping device as claimed in claim 2, wherein the front portion is disposed opposite the permanent magnet in the lower part.

7. The clamping device as claimed in claim 1, wherein the block and the lower part are comprised of nonmagnetic or non-magnetizable material.

8. The clamping device as claimed in claim 7, wherein the non-magnetizable material is polyetheretherketone, polyvinylchloride or polytetrafluoroethylene.

9. The clamping device as claimed in claim 2, wherein the underside of the front portion of the press-on fixture has a protective layer of synthetic material.

10. The clamping device as claimed in claim 1, wherein two blocks are provided, between which is located the press-on fixture.

11. A clamping device for holding a substrate, comprising:
a block disposed on a lower part of the clamping device having a press-on fixture disposed therein, wherein the press-on fixture is swivellably pivoted in the block and is comprised of a magnetizable material or contains a magnet, and that a pusher comprising a magnet is provided above one end of the press-on fixture.

12. The clamping device as claimed in claim 11, wherein the pusher is provided stationarily on the installation in a loading or unloading station.

13. A clamping device for holding a substrate, comprising:
a block disposed on a lower part of the clamping device having a press-on fixture disposed therein, wherein the press-on fixture is swivellably pivoted in the block and is comprised of a magnetizable material or contains a magnet, and that a pin comprising a magnet is provided above one end of the press-on fixture.

14. The clamping device as claimed in claim 11, wherein the pin is provided stationarily on the installation in a loading or unloading station.
